(19) United States
(12) Patent Application Publication
(10) Pub. No.: US 2015/0014806 A1
(43) Pub. Date: Jan. 15, 2015

(54) Image Sensor and Manufacturing Method Thereof

(71) Applicant: GALAXYCORE SHANGHAI LIMITED CORPORATION, Shanghai (CN)

(72) Inventors: Lixin Zhao, Shanghai (CN); Jieguang Huo, Shanghai (CN); Jie Li, Shanghai (CN)

(73) Assignee: GALAXYCORE SHANGHAI LIMITED CORPORATED, Shanghai (CN)

(21) Appl. No.: 14/377,550

(22) PCT Filed: Feb. 8, 2013
(86) PCT No.: PCT/CN2013/071582

§ 371 Date: Aug. 8, 2014

(30) Foreign Application Priority Data
Feb. 10, 2012 (CN) 201210030474.1

(51) Int. Cl. H01L 27/146

(52) U.S. Cl. CPC H01L 27/14643; H01L 27/14636; H01L 27/14683
USPC 257/448; 438/98

(57) ABSTRACT

The invention discloses an image sensor (100) and a method of fabricating the image sensor. The image sensor (100) includes: a substrate (101) with a metal interconnection layer (102) formed on a first side thereof; a first type of doped area (103) located in the substrate (101); a second type of doped area (105) located in the substrate (101) adjacent to the first type of doped area (103) to form a photoelectric diode; an electrode layer (107) located on a second side of the substrate (101), wherein the electrode layer (107) is light-transmissive; and an insulation layer (109) located between the electrode layer (107) and the substrate (101); wherein there is a predetermined potential difference between the electrode layer (107) and the substrate (101) such that a second type of conductive layer (111) is generated on the surface of the second side of the substrate (101).

### FIELD OF THE INVENTION

The present disclosure relates to the field of semiconductor technologies and more particularly to an image sensor and a method of fabricating the image sensor.

### BACKGROUND OF THE INVENTION

Conventional image sensors are typically categorized into a Charge Coupled

Device (CCD) image sensor and a Complementary Metal Oxide Semiconductor (CMOS) image sensor, where the CMOS image sensor has the advantages of a small volume, low power consumption, a low production cost, etc., so it is easy to integrate the CMOS image sensor, for example, in a handset, a notebook computer, a tablet computer and other portable electronic devices as a camera module to provide a digital imaging function.

The CMOS image sensor typically includes photoelectric diodes to collect and convert optical energy into a charge signal. Particularly the surface of a substrate where the photoelectric diodes are formed is doped with ions to form a pinning layer so as to lower dark current. The pinning layer is typically in contact with the substrate to thereby be provided with the same potential, and the potential of the photoelectric diodes is pinned at a constant value when they are fully depleted to thereby lower dark current.

However a substrate of a Back Side Illumination (BSI) image sensor typically needs to be thinned to 2 to 4 micrometers to thereby have photoelectric diodes exposed from the backside. Only then can doping ions be further injected into the backside of the substrate to form a pinning layer. It may be difficult for ion injection of the pinning layer to activate the injected ions through Rapid Thermal Annealing (RTA) due to the low thickness of the substrate, and typically laser annealing needs to be performed instead. However it may be difficult for laser annealing to ensure the uniformity of injected ion activation, and white dots may occur on the backside of the substrate, thus degrading the performance of the image sensor.

It is therefore desirable to provide an image sensor with a good pinning effect.

### SUMMARY OF THE INVENTION

In order to address the problem above, according to an aspect of the invention, there is provided an image sensor image sensor including: a substrate with a metal interconnection layer formed on a first side thereof; a first type of doped area located in the substrate; a second type of doped area located in the substrate adjacent to the first type of doped area to form a photoelectric diode; an electrode layer located on a second side of the substrate, wherein the electrode layer is light-transmissive; and an insulation layer located between the electrode layer and the substrate; wherein there is a predetermined potential difference between the electrode layer and the substrate such that a second type of conductive layer is generated on a surface of the second side of the substrate.

In an embodiment of the invention, the conductive electrode layer is formed on the surface of the substrate so that voltage can be applied to the electrode layer to thereby inductively generate the second type of conductive layer on the surface of the substrate. The conductive layer together with the first type of doped area therebelow constitute a pining diode, that is, the second type of conductive layer functions as a pinning layer of the produced image sensor to thereby suppress dark current.

As compared with the conventional image sensors, the thickness of the pinning layer becomes more uniform to thereby improve the pinning effect of the surface of the substrate and effectively lower dark current. Moreover the predetermined potential difference between the electrode layer and the substrate can be adjusted by varying the voltage of the electrode layer so that the thickness of the pinning layer can be adjusted by adjusting the varying predetermined potential difference to thereby adjust the pinning performance of the pinning layer.

Moreover since the electrode layer is light-transmissive, for example, the electrode layer includes one or more through-holes to transmit light or is made of a light-transmissive material to transmit light, the electrode layer on the second side of the substrate will impose no influence upon light sensing of the photoelectric diode in the image sensor.

In an embodiment, the first type of doped area is exposed from the second side of the substrate, and the predetermined potential difference causes the surface of the first type of doped area to be inverted into the second type of conductive layer.

In an embodiment, the second type of doped area is exposed from the second side of the substrate and covers the first type of doped area, and the predetermined potential difference causes the concentration of majority carriers in the surface of the second type of doped area to be increased.

In an embodiment, the electrode layer comprises one or more through-holes located on the photoelectric diode. These through-holes can improve the overall transmissivity of the electrode layer to thereby further improve the imaging effect.

In an embodiment, the shape of the through-hole is hexagonal.

In an embodiment, the area of the one or more through-holes is larger than 10% of the area of the photoelectric diode.

In an embodiment, the thickness of the electrode layer is no larger than 2000 angstrom.

In an embodiment, the electrode layer includes indium tin oxide, zinc oxide or the combination of titanium and titanium oxide.

In an embodiment, the image sensor further includes: an electrode interconnection layer located on the electrode layer to electrically lead out the electrode layer.

In an embodiment, the electrode interconnection layer includes tungsten, aluminum or copper.

In an embodiment, the electrode interconnection layer is located at the edge of the photoelectric diode. Since the electrode interconnection layer is typically made of a non-light-transmissive material, the electrode interconnection layer at the edge of the photoelectric diode can prevent crosstalk between the adjacent pixel elements of the image sensor.

In an embodiment, the thickness of the electrode interconnection layer ranges from 400 angstrom to 5000 angstrom. This can avoid an influence of the electrode interconnection layer upon the incidence of lights on the photoelectric diode and also lower a loss of voltage transmission on the thin electrode layer

According to another aspect of the invention, there is further provided a method of fabricating an image sensor, the method including: a. providing a substrate, wherein a metal interconnection layer is formed on a first side of the substrate, a first type of doped area and a second type of doped area adjacent thereto are formed in the substrate, and the first type of doped area and the second type of doped area constitute a photoelectric diode; b. forming an insulation layer on a second side of the substrate; and c. forming an electrode layer on the insulation layer, wherein the electrode layer is located on the substrate and light-transmissive.

The foregoing and other features of the invention will be expressly set forth below in the following detailed description.

### BRIEF DESCRIPTION OF DRAWINGS

The features, objects and advantages of the invention will become more apparent upon review of the following detailed description of non-limiting embodiments with reference to the drawings in which identical or like devices are denoted by identical or like reference numerals.

FIG. 1 illustrates an image sensor 100 according to an embodiment of the invention;

FIG. 2a and FIG. 2b illustrate an image sensor 200 according to another embodiment of the invention;

FIG. 2c illustrates a top view of an image sensor according to another embodiment of the invention;

FIG. 3 illustrates an image sensor 300 according to a still another embodiment of the invention;

FIG. 4 illustrates a method 400 of fabricating an image sensor according to an embodiment of the invention; and

FIG. 5a to FIG. 5e illustrate schematic sectional views of the method 400 of fabricating an image sensor of FIG. 4.

### DETAILED DESCRIPTION OF EMBODIMENTS

The making and use of the embodiments will be described below in details. However the particular embodiments to be described later are merely intended to illustrate particular modes in which the invention is practiced and used but not to limit the scope of the invention.

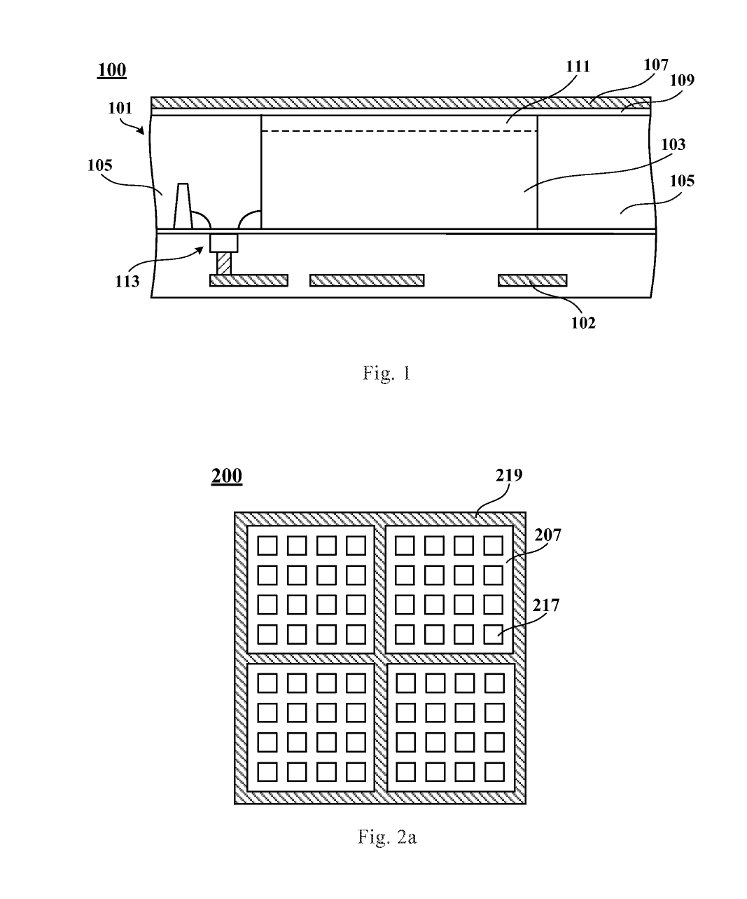

FIG. 1 illustrates an image sensor 100 according to an embodiment of the invention. The image sensor 100 is a side illumination image sensor. In some embodiments, the image sensor 100 includes one or more pixel elements, each of which can be embodied as a pixel structure including three transistors (3T) or four transistors (4T), i.e., including the photoelectric diode(s) and three or four MOS transistors used to control photo-induced charges to be transferred and to generate an output signal.

As illustrated in FIG. 1, the image sensor 100 includes: a substrate 101 with a metal interconnection layer 102 formed on a first side thereof;
an N-type doped area 103 located in the substrate 101;
a P-type doped area 105 located in the substrate 101 adjacent to the N-type doped area 103 to form a photoelectric diode or photoelectric diodes;
an electrode layer 107 located on a second side of the substrate 101 and partially located on the N-type doped area 103, wherein the electrode layer 107 is light-transmissive; and
an insulation layer 109 located between the electrode layer 107 and the substrate 101.
wherein there is a predetermined potential difference between the electrode layer 107 and the substrate 101 so that a P-type conductive layer 111 is generated on the surface of the second side of the substrate 101.

Particularly the first side of the substrate 101 is opposite to the second side thereof. Since the image sensor 100 is a side illumination image sensor, a plurality of MOS transistors 113, i.e., the aforesaid MOS transistors used to control photo-induced charges to be transferred and/or other types of MOS transistors, e.g., transfer transistors, reset transistors, row select transistors, source follower transistors, etc., are formed on the first side of the substrate 101. Moreover the metal interconnection layer 102 configured to connect these MOS transistors and to lead out pixel elements of the image sensor is also arranged on the first side of the substrate 101. Correspondingly the photoelectric diode(s) in the pixel elements of the image sensor 100 is exposed from the second side of the substrate 101 to sense light.

The substrate 101 includes therein the N-type doped area 103 and the P-type doped area 105. In some embodiments, the substrate 101 can be pre-doped with N-type ions, and the P-type doped area 105 is formed by further doping the substrate 101 with P-type ions. In some other embodiments, the substrate 101 can be pre-doped with P-type ions, and the N-type doped area 103 is formed by further doping the substrate 101 with N-type ions, and the substrate 101 can be backside-abraded or chemical-mechanical-polished so that the N-type doped area 103 is exposed from the second side of the substrate 101.

In a preferred embodiment, the P-type doped area 105 is located at the edge of the N-type doped area 103, for example, the P-type doped area 105 encompasses the N-type doped area 103. Since a PN junction is formed at the border area of the P-type doped area 105 and the N-type doped area 103 to form the photoelectric diode(s), such photoelectric diode(s) can be provided with a larger light-sensing region and consequentially with higher sensitivity.

In the embodiment of FIG. 1, the N-type doped area 103 is exposed from the second side of the substrate 101. There is a predetermined potential difference between the electrode layer 107 and the N-type doped area 103, for example, the potential of the electrode layer 107 is lower than the potential of the N-type doped area 103, so that majority carriers (i.e., electrons) in the N-type doped area 103 will be pushed away from the electrode layer 107, and thus the surface of the N-type doped area 103 proximate to the electrode layer 107 is inverted to be P-type doped. As such the P-type doped conductive layer 111, i.e., a pinning layer, is generated on the surface of the N-type doped area 103, i.e., the surface of the substrate 101. The P-type conductive layer 111 together with the non-inverted N-type doped area 103 therebelow constitute the pinning diode.

As can be apparent from FIG. 1, the P-type conductive layer 111 can extend to the border area of the N-type doped area 103 and the P-type doped area 105, so the P-type conductive layer 111 is connected with the P-type doped area 105 at the border area thereof. Since the P-type doped area 105 is typically embodied as a body area of the MOS transistors 113, the potential of the pinning layer is the same as that of the body area. Thus the potential of the photoelectric diode(s) will be pinned at a constant value when they are fully depleted to thereby lower dark current.

Since the electrode layer 107 is made of an electrically-conductive material, the potential of the electrode layer 107 is substantially uniform when predetermined voltage is applied thereto. Thus the predetermined potential difference between the electrode layer 107 and the N-type doped area 103 therebelow is substantially uniform so that the thickness of the formed P-type conductive layer 111 becomes more uniform. The uniform P-type conductive layer 111 can improve the pinning effect of the surface of the substrate 101 to thereby better lower dark current. Moreover the predetermined potential difference between the electrode layer 107 and the N-type doped area therebelow varies with varying voltage applied to the electrode layer 107, and correspondingly the thickness of the formed P-type conductive layer 111 due to inversion also varies. Thus the thickness of the P-type conductive layer 111 can be adjusted by varying the voltage applied to the electrode layer 107 to thereby adjust the pinning performance of the P-type conductive layer 111. Moreover since the electrode layer 107 is electrically-conductive, the electrode layer 107 can be electrically led out through contact holes and pads (not illustrated), and additional pins can be further formed to power the electrode layer 107. As can be appreciated, the electrode layer 107 can alternatively be powered by other structures in a practical application, for example, an electrode interconnection layer (not illustrated) is formed on the electrode layer 107 to be further electrically led out through contact holes.

The electrode layer 107 can be light-transmissive at the transmissivity, for example, of above 50%, for example, the electrode layer 107 includes one or more through-holes to transmit light or is made of light-transmissive material to transmit light. Since the electrode layer 107 is located on the photoelectric diode(s), i.e., on a light-sensing region of the image sensor, the highly light-transmissive electrode layer 107 can be prevented from excessively absorbing lights to thereby degrade the effect of sensing light. For example, the electrode layer 107 includes indium tin oxide, zinc oxide or the combination of titanium and titanium oxide. Preferably the thickness of the electrode layer 107 is no larger than 2000 angstrom. The lower the thickness of the electrode layer 107 is, the fewer it will absorb lights.

As compared with the prior art, in the embodiment of the invention, the electrode layer 107 can be formed on the substrate 101 in a deposition process to thereby avoid the injection of P-type ions to form the pinning layer and the subsequent laser annealing process. Thus the thickness of the P-type conductive layer 111 formed on the surface of the substrate 101 becomes more uniform, and also there will be a better imaging effect of the produced image sensor 100.

As can be apparent, in some embodiments, the doped area 103 can be replaced with P-type doping and the doped area 105 can be replaced with N-type doping to form the photoelectric diode(s) with the PN junction. Correspondingly the formed conductive layer 111 is replaced with N-type doping and constitutes together with the doped area 103 the pinning diode.

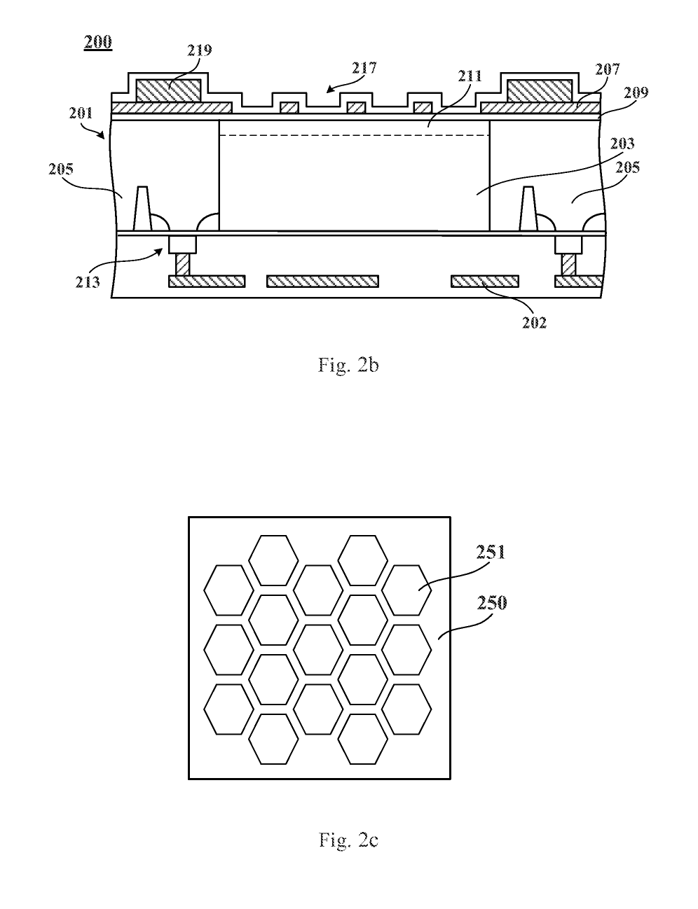

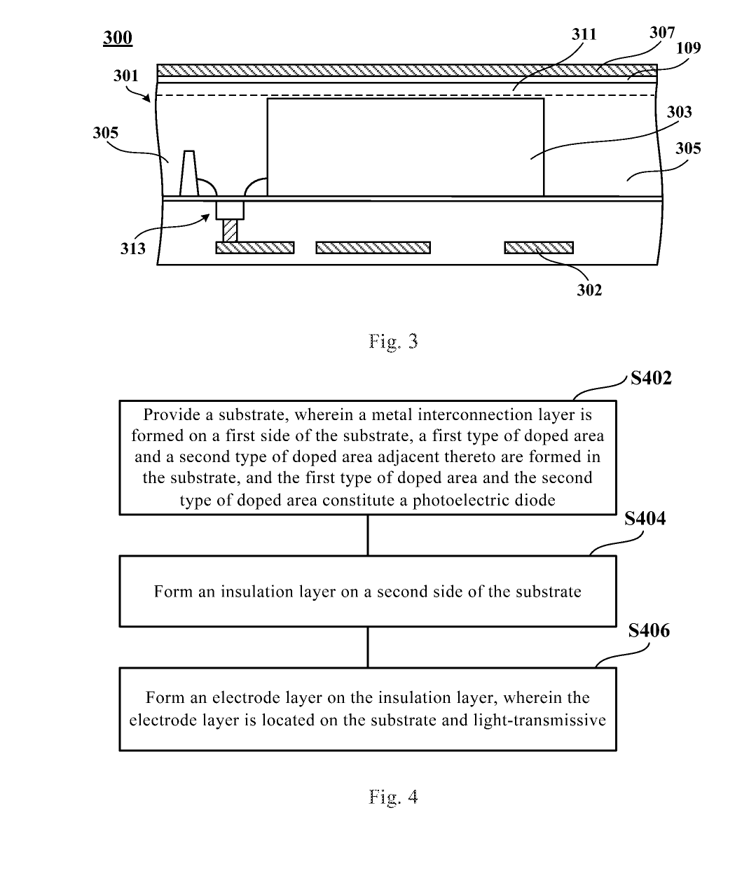

FIG. 2a and FIG. 2b illustrate an image sensor 200 according to another embodiment of the invention, where FIG. 2a exemplarily illustrates a top view of four pixel elements of the image sensor 200, and FIG. 2b illustrates a sectional view of one of the pixel elements.

As illustrated in FIG. 2a and FIG. 2b, the image sensor 200 includes:
a substrate 201 with a metal interconnection layer 202 formed on a first side thereof;
an N-type doped area 203 located in the substrate 201;
a P-type doped area 205 located in the substrate 201 adjacent to the N-type doped area 203 to form a photoelectric diode or photoelectric diodes;
an electrode layer 207 located on a second side of the substrate 201, wherein the electrode layer 207 is light-transmissive, and the electrode layer 207 includes one or more through-holes 217 located on the photoelectric diode(s); and
an insulation layer 209 located between the electrode layer 207 and the N-type doped area 203, wherein there is a predetermined potential difference between the electrode layer 207 and the substrate 201 so that a P-type conductive layer 211 is generated on the surface of the second side of the substrate 201.

In some embodiments, the through-holes 217 formed in the electrode layer 207 are further filled with other material, e.g., a passivation layer made of silicon oxide, silicon nitride or boron phosphate glass (BPSG). These materials are highly light-transmissive to thereby improve the overall transmissivity of the electrode layer 207 so as to further improve the imaging effect. Preferably the area of these through-holes 217 is larger than 10% of the area of the photoelectric diode(s), i.e., 10% of the area of the light sensing region per pixel element. The larger the area of the through-holes 217 is, the higher the overall transmissivity of the electrode layer 207 will be, and thus the better the image effect of the image sensor 200 will be.

In the embodiment illustrated in FIG. 2, there are sixteen through-holes 217 distributed uniformly on the electrode layer 207 corresponding to each pixel element. As can be appreciated, in a practical application, the number of pixel elements can vary with the area per pixel element, that is, both the aperture of each through-hole 217 and the space between adjacent through-holes 217 can vary.

In a preferred embodiment, the through-holes 217 are circular, square, hexagonal or the like with an aperture of below 0.5 micrometers. Since the N-type doped area 203 below the through-holes 217 is far way from the electrode layer 207, there is an insignificant influence of voltage applied to the electrode layer 207 upon the N-type doped area 203 below the through-holes 217. For the through-holes 217 with an aperture of below 0.5 micrometers, a strong electric field still can be maintained by the electrode layer 207 at the edge of the through-holes 217 so that the N-type doped area 203 below the central region of the through-holes 217 is inverted to thereby prevent the imaging quality of the image sensor 200 from being degraded as a result of the non-uniform thickness of the pinning layer 211. Optionally in some other embodiments, the through-holes 217 can alternatively be rectangular, helical or other light-transmissive shapes.

In some embodiments, an electrode interconnection layer 219 is further formed on the electrode layer 207 to have the electrode layer 207 electrically led out. For example, the electrode interconnection layer 219 can be made of aluminum, tungsten, copper or other conductive materials. The electrode interconnection layer 219 located on the electrode layer 207 can be in contact with the electrode layer 207 to be electrically connected therewith. Thus voltage can be applied to the electrode interconnection layer 219 to thereby result in a predetermined potential difference between the electrode layer 207 and the N-type doped area 203 therebelow. Since the electrode interconnection layer 219 is typically made of a non-light-transmissive material, the electrode interconnection layer 219 can be located at the edge of the photoelectric diode(s) (i.e., a light sensing region), typically at the border region of the different pixel elements. Moreover the electrode interconnection layer 219 at the edge of the pixel elements can prevent crosstalk between the adjacent pixel elements of the image sensor to thereby improve the performance of the image sensor 200. In a preferred embodiment, the thickness of the electrode interconnection layer 219 ranges from 400 angstrom to 5000 angstrom. This can avoid the influence of the electrode interconnection layer 219 upon the incidence of lights on the photoelectric diode(s) and also lower the loss of voltage transmission on the thin electrode layer 207 to thereby improve the uniformity of the conductive layer 21 so as to achieve the good pinning performance and imaging quality of the image sensor 200.

FIG. 2c illustrates a top view of the image sensor according to another embodiment of the invention.

As illustrated in FIG. 2c, in the image sensor, there are a plurality of through-holes 251 in an electrode layer 250, and the shape of these through-holes 251 is hexagonal, e.g., regularly hexagonal. The hexagonal through-holes 251 are arranged compactly so that lights can transmit therethrough to illuminate directly a sensing region therebelow and the sensing region below the through-holes 251 can be affected by voltage applied to the electrode layer 250 to have the distribution of majority carriers therein changed. Thus the image sensor including the electrode layer with the hexagonal through-holes can have both the good pinning effect and high sensitivity.

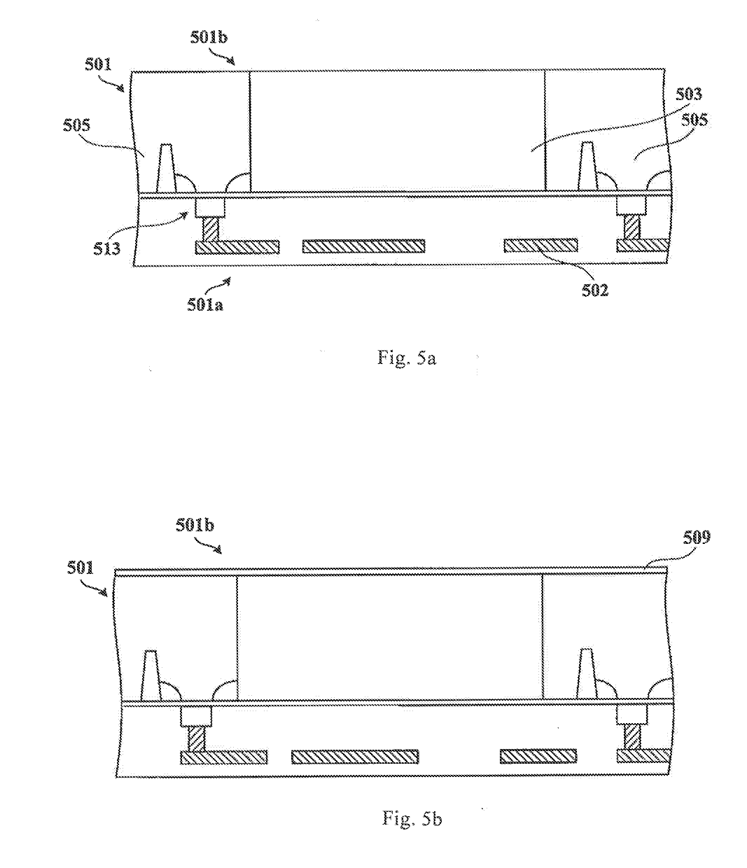

FIG. 3 illustrates an image sensor 300 according to still another embodiment of the invention.

As illustrated in FIG. 3, the image sensor 300 includes:
a substrate 301 with a metal interconnection layer 302 formed on a first side thereof;
an N-type doped area 303 located in the substrate 301;
a P-type doped area 305 located in the substrate 301 adjacent to the N-type doped area 303 to form a photoelectric diode or photoelectric diodes;
an electrode layer 307 located on a second side of the substrate 301 and located partially on the N-type doped area 303, wherein the electrode layer 307 is light-transmissive; and
an insulation layer 309 located between the electrode layer 307 and the substrate 301.
wherein there is a predetermined potential difference between the electrode layer 307 and the substrate 301 so that a P-type conductive layer 311 is generated on the surface of the second side of the substrate 301.

In the embodiment in FIG. 3, the P-type doped area 305 is exposed from the second side of the substrate 301 and covers the N-type doped area 303 so as to avoid the N-type doped area 303 from being exposed from the second side of the substrate 301. Thus there is a predetermined potential difference between the electrode layer 307 and the surface of the substrate 310, i.e., the surface of the P-type doped area 305, for example, the potential of the electrode layer 307 is lower than the potential of the P-type doped area 305, so that majority carriers (i.e., holes) in the P-type doped area 305 are drawn proximate to the electrode layer 307 to thereby improve the concentration of majority carriers on the surface of the P-type doped area 305 proximate to the electrode layer 307. Thus the P-type conductive layer 311 doped at the concentration far above than that inside the P-type doped area 305, i.e., a pinning layer, is generated on the surface of the P-type doped area 305, i.e., the surface of the substrate 301. The P-type conductive layer 311 constitutes together with the non-inverted N-type doped area 303 therebelow the pinning diode.

As can be appreciated, the thickness of the P-type conductive layer 311 varies with the predetermined potential difference between the electrode layer 307 and the P-type doped area 305. Thus the thickness of the P-type conductive layer 311 can be adjusted by varying the voltage applied to the electrode layer 307 to thereby adjust the pinning performance of the P-type conductive layer 311.

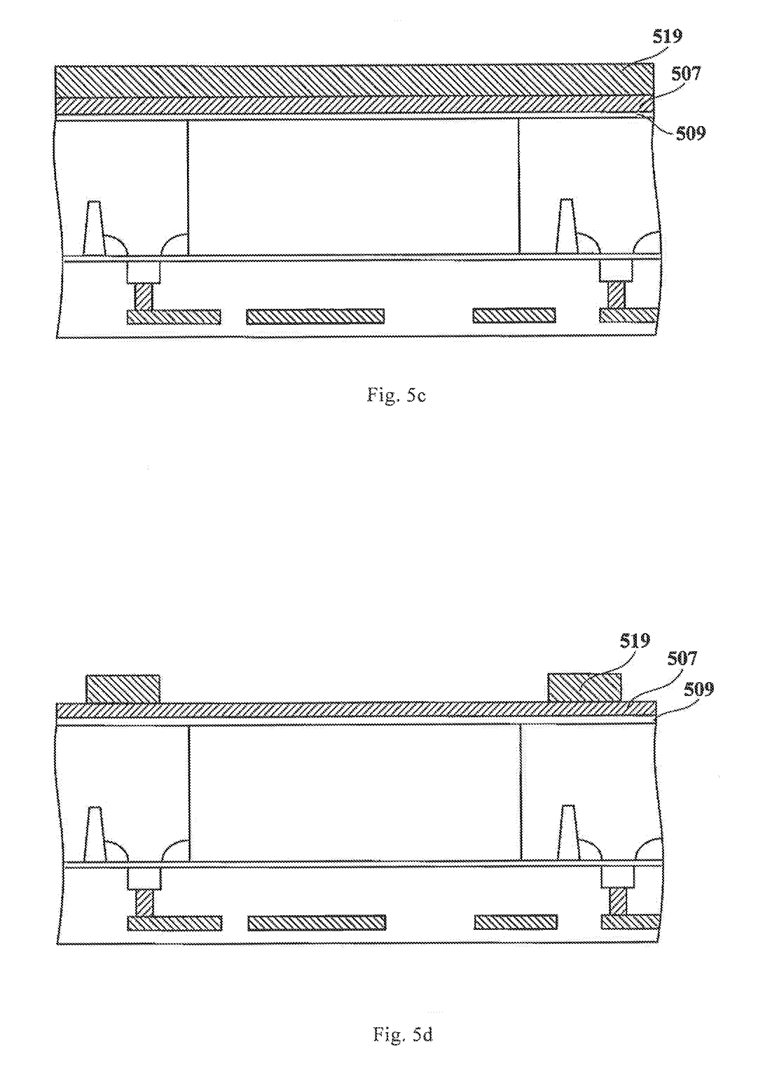

FIG. 4 illustrates a method 400 of fabricating an image sensor according to an embodiment of the invention.

As illustrated in FIG. 4, the method 400 of fabricating an image sensor includes:
the step S402 of providing a substrate, wherein a metal interconnection layer is formed on a first side of the substrate, a first type of doped area and a second type of doped area adjacent thereto are formed in the substrate, and the first type of doped area and the second type of doped area constitute a photoelectric diode or photoelectric diodes.
the step S404 of forming an insulation layer on a second side of the substrate; and
the step S406 of forming an electrode layer on the insulation layer, wherein the electrode layer is located on the substrate and is light-transmissive.

In an embodiment, the first type of doped area is exposed from the second side of the substrate. In another embodiment, the second type of doped area is exposed from the second side of the substrate and covers the first type of doped area to thereby avoid the first type of doped area from exposing from the second side of the substrate

As can be appreciated, in some embodiments, the first type of doped area is of N-type doping, the second type of doped area is of P-type doping, and the second type of conductive layer is of P-type doping. Or alternatively in some embodiments, the first type of doped area is of P-type doping, the second type of doped area is of N-type doping, and the second type of conductive layer is of N-type doping. Hereinafter the description will be made using the first type of doped area being of N-type doping, the second type of doped area being of P-type doping and the second type of electrically-conductive layer being of P-type doping as example, and those skilled in the art can appreciate an embodiment with an opposite doping type or electrical conductivity can also be fabricated in a similar method thereof.

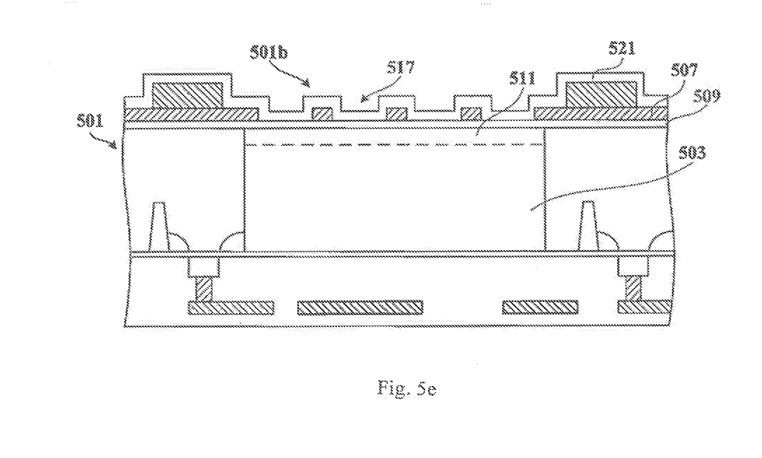

FIG. 5a to FIG. 5e illustrate schematic sectional views of a method of fabricating the image sensor of FIG. 4. Next the method of fabricating an image sensor will be further described with reference to FIG. 4 and FIG. 5a to FIG. 5e.

As illustrated in FIG. 5a, a substrate 501 with a first side 501a and a second side 501b opposite thereto is provided, wherein an N-type doped area 503 and a P-type doped area 505 adjacent thereto are formed in the substrate 501.

In FIG. 5a, the N-type doped area 503 is exposed from the second side 501b of the substrate 501, and the exposed N-type doped area 503 can be used to collect lights and to inductively generate charges. Correspondingly the PN junction is formed at the border region between the P-type doped area 505 and the N-type doped area 503 to thereby form the photoelectric diode(s) in pixel elements of the image sensor. In the embodiment illustrated in FIG. 5a, the P-type doped area 505 is also exposed from the second side 501b of the substrate 501, and the P-type doped area 505 is located at the edge of the N-type doped area 503, so that the N-type doped area 503 can be isolated across the different pixel elements by the traversing P-type doped area 505 without any additional isolation structure, e.g., a trench-like isolation structure. As can be appreciated, in other embodiments, the P-type doped area 505 may alternatively not be exposed from the second side 501b of the substrate 501, and the respective pixel elements can be isolated by a trench-like isolation structure (not illustrated) located outside of the P-type doped area 505.

MOS transistors of the pixel elements are formed in the N-type doped area 503. Moreover a metal interconnection layer 502 is further formed on the first side 501a of the substrate 501 to have these MOS transistors electrically led out to thereby drive electrically and read the signal from the respective pixel elements.

In some embodiments, the substrate 501 can be pre-doped with N-type ions, and the P-type doing area 505 can be formed by further doping the substrate 501 with P-type ions. In some other embodiments, the substrate 501 can be pre-doped with P-type ions, and the N-type doped area 503 can be formed by further doping the substrate 501 with N-type ions, and the substrate 501 can be backside-abraded so that the N-type doped area 503 is exposed from the second side 501b of the substrate 501.

It shall be noted that in some embodiments, the N-type doped area 503 may alternatively not be exposed from the second side 501b of the substrate 501, that is, the N-type doped area 503 is covered by the P-type doing area 505. For example, the substrate 501 is P-type doped, the well-shaped N-type doped area 503 is formed on the first side of the substrate, and the substrate 501 is abraded or etched from the second side thereof. The abrading and etching stops while approaching the top of the well-shaped N-type doped area 503 (proximate to the second side 501b of the substrate 501) to thereby reserve a part of the substrate 501 located above the well-shaped N-type doped area 503.

As illustrated in FIG. 5b, an insulation layer 509 is formed on the second side 501b of the substrate 501. The insulation layer 509 comprises silicon oxide, silicon nitride or the combination thereof, for example.

As illustrated in FIG. 5c, an electrode layer 507 is formed on the insulation layer 509. The electrode layer 507 is made of an electrically-conductive material. Preferably the light-transmissive electrically-conductive material, e.g., indium tin oxide, zinc oxide or the combination of titanium and titanium oxide, can be deposited on the insulation layer 509 to form the electrode layer 507. Preferably the thickness of the electrode layer 507 is below 2000 angstrom. In practice, the electrode layer 507 can be deposited in a chemical vapor deposition process.

Next an electrode interconnection layer 519 is further deposited on the electrode layer 507. The electrode interconnection layer 519 can be formed of tungsten, aluminum, copper or other electrically-conductive materials, for example, through spraying or other physical vapor deposition process. In an embodiment, the thickness of the electrode interconnection layer 519 ranges from 400 angstrom to 5000 angstrom.

As illustrated in FIG. 5d, the electrode interconnection layer 519 is patterned to expose a part of the electrode layer 507. In a preferred embodiment, the electrode interconnection layer 519 above the photoelectric diode(s) (primarily above the N-type doped area 503) is removed, while only a part of the electrode interconnection layer 519 on the P-type doped area 505, i.e., a part of the electrode interconnection layer 519 at the edge of the photoelectric diode(s), is reserved.

Optionally after the electrode interconnection layer 519 is patterned, as illustrated in FIG. 5e, the exposed electrode layer 507 is patterned to expose a part of the insulation layer 509 so that one or more through-holes 517 located on the photoelectric diode(s) are formed in the electrode layer 507. In some embodiments, the area of the formed through-holes 517 is larger than 10% of the area of the photoelectric diode(s). The formed through-holes 517 have the photoelectric diode(s) in the substrate 501 partially exposed through the insulation layer 509 to thereby improve the overall transmissivity of the electrode layer 507. The through-holes 517 can be of various shapes, e.g., square, rectangle, circle, hexagon or other appropriate shapes. In a preferred embodiment, the through-holes 517 can be hexagonal.

Next a passivation layer 521 is further formed on the second side 501b of the substrate 501, for example, by depositing silicon oxide, silicon nitride or other appropriate materials. The formed passivation layer 521 can protect the electrode layer 507, the electrode interconnection layer 519 and the N-type doped area 503.

In a practical application, an optical filter film and micro-lens (not illustrated) can be further formed on the second side 501b of the substrate 501 after the passivation layer 521 is formed.

As can be appreciated, in some embodiments, the electrode layer can be electrically led out by fabricating contact holes directly instead of forming the electrode interconnection layer and/or the through-holes after the electrode layer is formed.

As compared with the prior art, in the embodiment of the invention, the electrode layer 507 can be formed on the substrate 501 in a deposition process to thereby avoid the injection of P-type ions to form the pinning layer and the subsequent laser annealing process. Thus the thickness of the conductive layer 511 formed by applying voltage to the electrode layer 507 becomes more uniform, and there will be a better imaging effect of the produced image sensor.

Although the invention has been described in details in the drawings and the foregoing description, it shall be appreciated the description is merely intended to be illustrative and exemplary but not to be limiting; and the invention will not be limited to the embodiments described above.

Those ordinarily skilled in the art can appreciate and make other variations to the disclosed embodiments upon review of the description, the disclosure and the drawings as well as the appended claims. In the claims, the term “comprising/comprises” shall not preclude another element or step, and the term “a” or “an” shall not preclude plural. Functions of a plurality of technical features recited in the claims may be performed by an element in a practical application of the invention. Any reference numerals in the claims shall not be construed to limit the scope of the invention.

1. An image sensor, comprising:
a substrate with a metal interconnection layer formed on a first side thereof;
a first type of doped area located in the substrate;
a second type of doped area located in the substrate adjacent to the first type of doped area to form a photoelectric diode;
an electrode layer located on a second side of the substrate, wherein the electrode layer is light-transmissive; and
an insulation layer located between the electrode layer and the substrate;
wherein there is a predetermined potential difference between the electrode layer and the substrate such that a second type of conductive layer is generated on a surface of the second side of the substrate.

2. The image sensor according to claim 1, wherein the first type of doped area is exposed from the second side of the substrate, and the predetermined potential difference causes a surface of the first type of doped area to be inverted into the second type of conductive layer.

3. The image sensor according to claim 1, wherein the second type of doped area is exposed from the second side of the substrate and covers the first type of doped area, and the predetermined potential difference causes concentration of majority carriers in a surface of the second type of doped area to be increased.

4. The image sensor according to claim 1, wherein the electrode layer comprises one or more through-holes located on the photoelectric diodes.

5. The image sensor according to claim 4, wherein an area of the one or more through-holes is larger than 10% of an area of the photoelectric diode.

6. The image sensor according to claim 4, wherein a shape of each of the one or more through-holes is hexagonal.

7. The image sensor according to claim 1, wherein a thickness of the electrode layer is no larger than 2000 angstrom.

8. The image sensor according to claim 1, wherein the electrode layer comprises indium tin oxide, zinc oxide or a combination of titanium and titanium oxide.

9. The image sensor according to claim 1, further comprising:
an electrode interconnection layer located on the electrode layer to electrically lead out the electrode layer.

10. The image sensor according to claim 9, wherein the electrode interconnection layer comprises tungsten, aluminum or copper.

11. The image sensor according to claim 9, wherein the electrode interconnection layer is located at an edge of the photoelectric diode.

12. The image sensor according to claim 9, wherein a thickness of the electrode interconnection layer ranges from 400 angstrom to 5000 angstrom.

13. A method of fabricating an image sensor, the method comprising:
a. providing a substrate, wherein a metal interconnection layer is formed on a first side of the substrate, a first type of doped area and a second type of doped area adjacent thereto are formed in the substrate, and the first type of doped area and the second type of doped area constitute a photoelectric diode;
b. forming an insulation layer on a second side of the substrate; and
c. forming an electrode layer on the insulation layer, wherein the electrode layer is located on the substrate and light-transmissive.

14. The method according to claim 13, wherein the first type of doped area is exposed from the second side of the substrate.

15. The method according to claim 13, wherein the step c further comprises:
forming in the electrode layer one or more through-holes located on the photoelectric diode.

16. The method according to claim 15, wherein a shape of each of the one or more through-holes is hexagonal.

17. The method according to claim 15, wherein an area of the one or more through-holes is larger than 10% of an area of the photoelectric diode.

18. The method according to claim 13, wherein a thickness of the electrode layer is no larger than 2000 angstrom.

19. The method according to claim 13, wherein the electrode layer comprises indium tin oxide, zinc oxide or a combination of titanium and titanium oxide.

20. The method according to claim 13, wherein after the step c, the method further comprises:
forming an electrode interconnection layer on the electrode layer.

21. The method according to claim 20, wherein the electrode interconnection layer comprises tungsten, aluminum or copper.

22. The method according to claim 20, wherein the electrode interconnection layer is located at an edge of the photoelectric diode.

23. The method according to claim 20, wherein a thickness of the electrode interconnection layer ranges from 400 angstrom to 5000 angstrom.
